(19) United States
(12) Patent Application Publication
(10) Pub. No.: US 2025/0241068 A1
(43) Pub. Date: Jul. 24, 2025

(54) THERMAL-PROTECTION TRANSIENT VOLTAGE SUPPRESSOR (TVS)

(71) Applicant: XIAMEN SET ELECTRONICS CO., LTD., Xiamen (CN)

(72) Inventors: Luquan LUO, Xiamen (CN); Xianggui ZHANG, Xiamen (CN); Yuecong TANG, Xiamen (CN); Jianguo JIANG, Xiamen (CN)

(73) Assignee: XIAMEN SET ELECTRONICS CO., LTD., Xiamen (CN)

(21) Appl. No.: 18/685,511

(22) PCT Filed: May 13, 2022
(86) PCT No.: PCT/CN2022/092832

§ 371 Date: Feb. 22, 2024

(30) Foreign Application Priority Data
Aug. 31, 2021 (CN) 202122084102.4

(51) Int. Cl. H10D 89/60

(52) U.S. Cl. CPC H10D 89/60

(57) ABSTRACT

A thermal-protection transient voltage suppressor (TVS) is provided, including a housing, a cover plate, a TVS assembly, and a pin electrode, where the housing and the cover plate are buckled to form an accommodating cavity that accommodates the TVS assembly and the pin electrode; the TVS assembly includes an inner frame and a TVS chip accommodated in the inner frame; and the pin electrode extends outside the accommodating cavity and is equipped with a surface mounting region on an extending portion for surface mounting and soldering. The present disclosure improves a speed of starting thermal protection, provides a surface mounting and soldering method, and adopts a thermal resistance design for the housing and a pin to prevent a low-temperature solder joint from being affected by a high temperature region of reflow soldering.

### CROSS REFERENCE TO THE RELATED APPLICATIONS

This application is the national phase entry of International Application No. PCT/CN2022/092832, filed on May 13, 2022, which is based upon and claims priority to Chinese Patent Application No. 202122084102.4, filed on Aug. 31, 2021, the entire contents of which are incorporated herein by reference.

### TECHNICAL FIELD

The present disclosure relates to the technical field of overvoltage protection, and in particular, to a thermal-protection transient voltage suppressor (TVS).

### BACKGROUND

As an overvoltage protection device, a transient voltage suppressor (TVS) is mainly used to discharge a surge current and accurately clamp a voltage.

An existing thermal-protection TVS does not start thermal protection quickly enough in a failure state, especially has a high requirement for a breaking capacity. For example, when a current reaches 150 A, an arc is often generated during the thermal protection, and in a severe case a product fire is caused, resulting in equipment damage. At present, single onboard soldering is commonly used on the market. In this method, a pin electrode is inserted into a printed circuit board (PCB) for soldering, and cannot be soldered together with a patch device through reflow soldering. As a result, secondary wave soldering is required, affecting production efficiency of a customer. In addition, a melting point of a fusible alloy for the thermal protection usually ranges from 140° C. to 220° C., which is much lower than a temperature in a high temperature range of 260° C. to 280° C. in the reflow soldering. Therefore, it is easy to cause a product failure in a soldering process.

### SUMMARY

In view of the aforementioned shortcomings in the prior art, the present disclosure adds a thermal protection assistance device to a TVS to improve a speed of starting thermal protection, provides a surface mounting and soldering method, and adopts a thermal resistance design for a housing and a pin to prevent a low-temperature solder joint from being affected by a high temperature region of reflow soldering.

To achieve the above objective, the present disclosure adopts following technical solutions:

A thermal-protection TVS includes a housing, a cover plate, a TVS assembly, and a pin electrode, where the housing and the cover plate are buckled to form an accommodating cavity that accommodates the TVS assembly and the pin electrode; the TVS assembly includes an inner frame and a TVS chip accommodated in the inner frame; and the pin electrode extends outside the accommodating cavity and is equipped with a surface mounting region on an extending portion for surface mounting and soldering.

Optionally, the pin electrode includes a main body of a straight-plate shape and a bending portion connected to the main body, the bending portion sequentially includes a multifunctional region, the surface mounting region perpendicular to the multifunctional region, and a guiding and fixing functional region, and a step is formed between the guiding and fixing functional region and the surface mounting region.

Optionally, the housing and the cover plate each are provided with a hole corresponding to the pin electrode, the bending portion of the pin electrode extends out of the accommodating cavity from the hole, and the multifunctional region, the surface mounting region, and the guiding and fixing functional region are exposed outside the accommodating cavity.

Optionally, the cover plate is provided with a cavity corresponding to the pin electrode, and the guiding and fixing functional region of the pin electrode is embedded in the cavity of the cover plate.

Optionally, the pin electrode is provided with at least one thermal resistance through-hole.

Optionally, an air gap of 0.1 mm to 1.5 mm is reserved between the housing and the main body of the pin electrode in the accommodating cavity.

Optionally, the pin electrode has a cross-sectional area of 0.1 mm² to 5 mm², a surface mounting portion has a soldering area of 1 mm² to 75 mm², and the pin electrode has a thickness of 0.2 mm to 1.5 mm.

Optionally, the TVS assembly further includes a reed electrode and a thermal protection assistance device, the reed electrode is provided with a notch, and the thermal protection assistance device is disposed in the notch of the reed electrode, where the thermal protection assistance device includes a sliding member and an elastic member, one end of the elastic member is connected to the inner frame and the other end is connected to the sliding member, and the sliding member is subjected to elastic force of the elastic member to enable the reed electrode to quickly trip and bounce up.

Optionally, the elastic member is a compressed spring, with one end abutting against the inner frame, the sliding member is provided with a hole to accommodate the other end of the compressed spring, and the sliding member is pushed by the compressed spring to enable the reed electrode to quickly trip and bounce up.

Optionally, the elastic member is a tension spring, the sliding member is provided with a convex column, and the inner frame is provided with a lug boss. One end of the tension spring is hooked onto the convex column of the sliding member, and the other end is hooked onto the lug boss of the inner frame. The sliding member receives tension from the tension spring to enable the reed electrode to quickly trip and bounce up.

Optionally, the pin electrode includes a first pin electrode, a second pin electrode, a third pin electrode, and a fourth pin electrode, outer edges of the first pin electrode and the fourth pin electrode are aligned, and outer edges of the second pin electrode and the third pin electrode are aligned.

Optionally, the pin electrode includes a first pin electrode, a second pin electrode, a third pin electrode, and a fourth pin electrode, there is a gap between an extension line of an outer edge of the first pin electrode and an extension line of an inner edge of the fourth pin electrode, and there is a gap between an extension line of an outer edge of the second pin electrode and an extension line of an inner edge of the third pin electrode.

The present disclosure has following beneficial effects: The housing and the cover plate form the accommodating cavity, reserving only the hole for the pin electrode to pass through. This prevents a fusible alloy from being melted and disconnected due to hot air circulation during reflow soldering. The at least one thermal resistance through-hole on the pin electrode can be used to prevent heat on the surface mounting region from being transferred to a fusible alloy point. The air gap of 0.1 mm to 1.5 mm is reserved between the housing and the pin electrode in the accommodating cavity, which prevents heat absorbed by the housing from being directly transferred to a solder point of the fusible alloy. The pin electrode is provided with the guiding and fixing functional region, the surface mounting region, and the multifunctional region. The guiding and fixing functional region is embedded in the cavity to achieve stabilization and ensure consistency between various planes of various surface mounting regions. The surface mounting region is used for surface mounting and soldering. The multifunctional region can be used to detect, by using a charge-coupled device (CCD) or other methods, whether the surface mounting region has inveracious soldering or excess soldering. In addition, the multifunctional region can also be used as a side soldering region to meet different soldering demands. The thermal protection assistance device composed of the sliding member and the elastic member helps the reed electrode to quickly trip and bounce up, and the sliding member slides to interrupt an arc, avoiding a fire.

### BRIEF DESCRIPTION OF THE DRAWINGS

FIG. 1 is an exploded view of a TVS according to an embodiment of the present disclosure;

FIG. 2 is a schematic diagram of a thermal protection assistance device installed in an inner frame according to an embodiment of the present disclosure;

FIG. 3 is a three-dimensional schematic diagram of a thermal protection assistance device and a reed electrode according to an embodiment of the present disclosure;

FIG. 4 is a stereoscopic diagram of a pin electrode according to an embodiment of the present disclosure;

FIG. 5 is a three-dimensional schematic diagram of a TVS without a housing according to an embodiment of the present disclosure;

FIG. 6 is a stereoscopic diagram of a cover plate according to an embodiment of the present disclosure;

FIGS. 7A-7B are a top view of a TVS without a housing and a cutaway view of the TVS along line A-A according to an embodiment of the present disclosure;

FIG. 8 is a partial enlarged view of the cutaway view in FIG. 7B;

FIG. 9 is a stereoscopic diagram of a TVS according to an embodiment of the present disclosure;

FIG. 10 is an exploded view of a TVS according to another embodiment of the present disclosure;

FIG. 11 is a schematic diagram of a thermal protection assistance device installed in an inner frame according to another embodiment of the present disclosure;

FIG. 12 is a schematic diagram of a second TVS chip according to another embodiment of the present disclosure;

FIG. 13 is a three-dimensional schematic diagram of a TVS without a housing according to another embodiment of the present disclosure;

FIG. 14 is a bottom view of a TVS according to another embodiment of the present disclosure; and

FIG. 15 is a principle diagram of a TVS according to the present disclosure.

11 Housing
12 First inner frame
121 First buckle
122 Limiting protrusion
13 First reed electrode
131 First end
132 Second end
14 First TVS chip
15 Second TVS chip
151 First electrode
152 Second electrode
153 Gap
16 Second reed electrode
161 Reed buckle
17 Second inner frame
171 Second buckle
172 Recess
18 First pin electrode
181 Multifunctional region of the first pin electrode
182 Surface mounting region of the first pin electrode
183 Guiding and fixing functional region of the first pin electrode
19 Second pin electrode
191 Multifunctional region of the second pin electrode
192 Surface mounting region of the second pin electrode
193 Guiding and fixing functional region of the second pin electrode
20 Cover plate
201 First cavity
202 Second cavity
203 Limiting member
21 Third pin electrode
211 Multifunctional region of the third pin electrode
212 Surface mounting region of the third pin electrode
213 Guiding and fixing functional region of the third pin electrode
22 Fourth pin electrode
221 Multifunctional region of the fourth pin electrode
222 Surface mounting region of the fourth pin electrode
223 Guiding and fixing functional region of the fourth pin electrode
24 First spring
25 Second spring
26 First sliding member
27 Second sliding member

### DETAILED DESCRIPTION OF THE EMBODIMENTS

To understand the above objectives, features, and advantages of the present disclosure more clearly, the present disclosure is further described in detail below with reference to the accompanying drawings and specific implementations. It should be noted that the implementations of the present disclosure or the features in the implementations may be combined with each other in a non-conflicting manner. Many specific details are set forth in the following description to facilitate a full understanding of the present disclosure. The described implementations are merely some rather than all of the implementations of the present disclosure. All other implementations obtained by those of ordinary skill in the art based on the implementations of the present disclosure without creative efforts should fall within the protection scope of the present disclosure.

### Embodiment 1

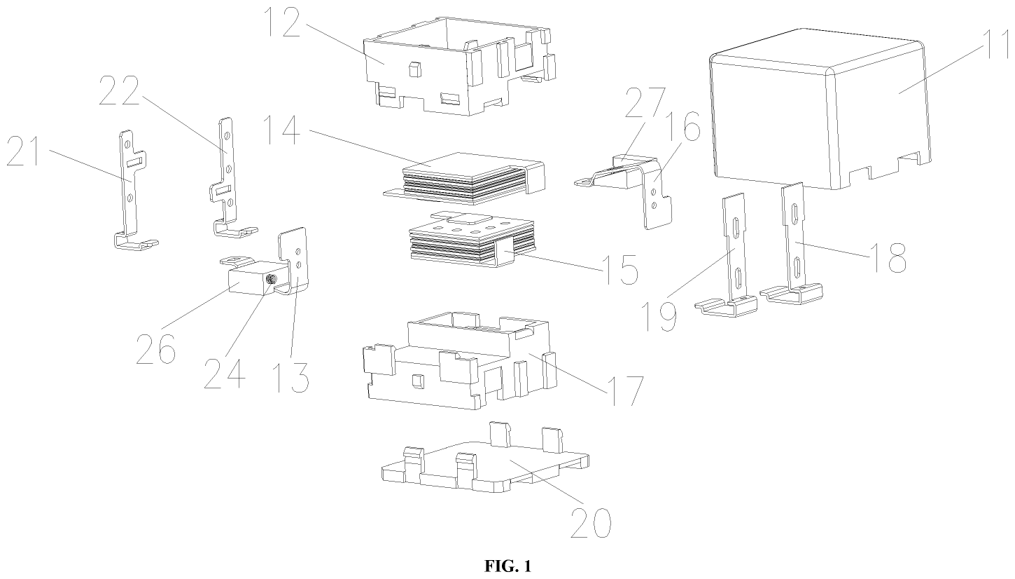

As shown in FIG. 1, this embodiment discloses a structure of a thermal-protection TVS. The thermal-protection TVS includes housing 11, first inner frame 12, first reed electrode 13, first TVS chip 14, second TVS chip 15, second reed electrode 16, second inner frame 17, first pin electrode 18, second pin electrode 19, cover plate 20, third pin electrode 21, fourth pin electrode 22, first spring 24, second spring 25, first sliding member 26, and second sliding member 27. An accommodating groove with an upward opening is provided on one side of the first inner frame 12 to accommodate the first TVS chip 14, and a half-groove with a downward opening is provided on another side of the first inner frame 12 to accommodate a first thermal protection assistance device and the first reed electrode 13. The second inner frame 17 is disposed in an opposite direction to the first inner frame. An accommodating groove with a downward opening is provided on one side of the second inner frame to accommodate the second TVS chip 15, and a half-groove with an upward opening is provided on another side of the first inner frame 17 to accommodate a second thermal protection assistance device and the second reed electrode 16.

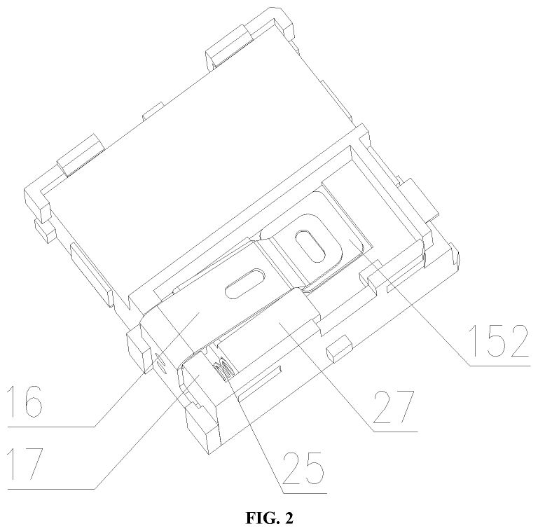

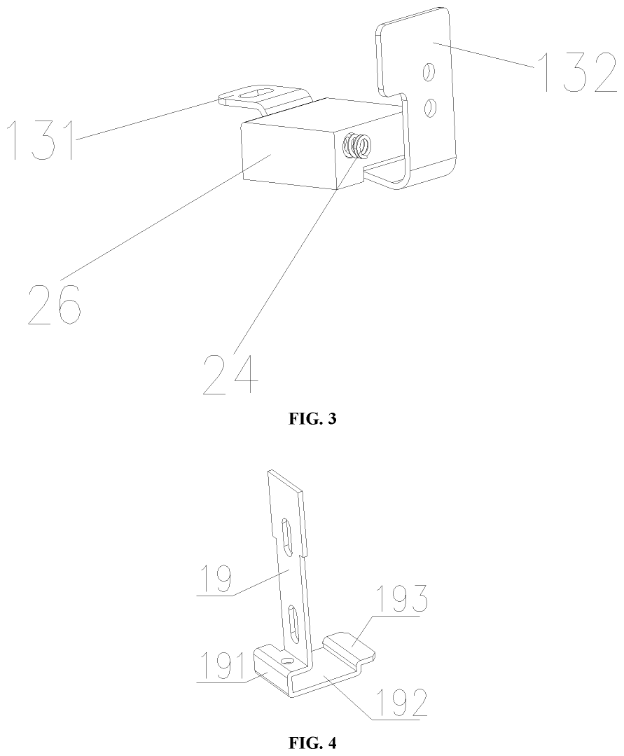

Referring to FIG. 2 and FIG. 3, the first reed electrode 13 includes first end 131 and second end 132. The first TVS chip 14 and the first end 131 of the first reed electrode 13 are soldered by using a fusible alloy to form a first thermal tripping device. One end of the first spring 24 abuts against the first inner frame 12, and the other end is embedded in the first sliding member 26. The first spring 24 and the first sliding member 26 form the first thermal protection assistance device, which is placed in a notch between the first end 131 and the second end 132 of the first reed electrode 13. Similarly, the second reed electrode 16 includes a first end and a second end. The second TVS chip 15 and the first end of the second reed electrode 16 are soldered by using the fusible alloy to form a second thermal tripping device. One end of the second spring 25 abuts against the second inner frame 17, and the other end is embedded in the second sliding member 27. The second spring 25 and the second sliding member 27 form the second thermal protection assistance device, which is placed in a notch between the first end and the second end of the second reed electrode 16. The first thermal protection assistance device and the second thermal protection assistance device are centrosymmetrically installed. There may be one or two first springs 24 and one or two second springs 25. When tripping occurs, the first sliding member 26 receives thrust of the first spring 24 to push the first reed electrode 13 to quickly trip and bounce up. The first sliding member 26 slides and interrupts an arc, avoiding a fire. Similarly, when tripping occurs, the second sliding member 27 receives thrust of the second spring 25 to push the second reed electrode 16 to quickly trip and bounce up. The second sliding member 27 slides and interrupts an arc, avoiding a fire.

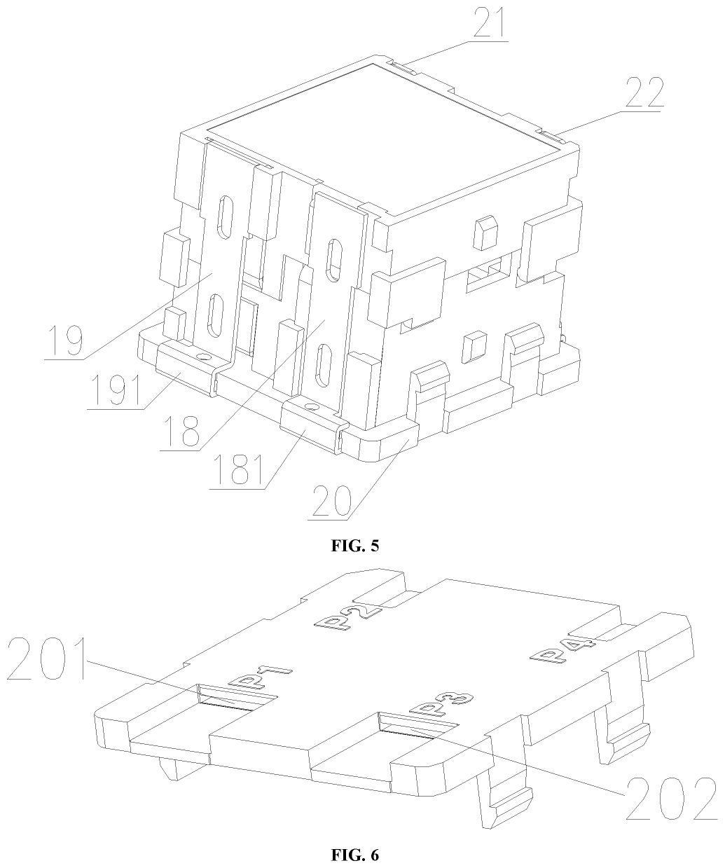

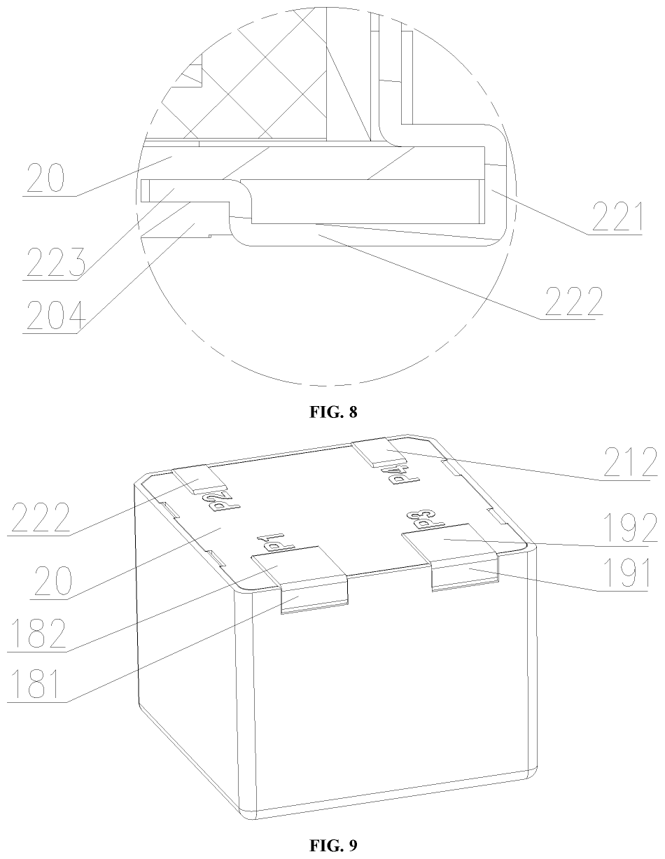

As shown in FIG. 4 to FIG. 9, the first pin electrode 18 in the present disclosure includes a main body of a straight-plate shape and a bending portion connected to the main body. The bending portion sequentially includes multifunctional region 181, surface mounting region 182 perpendicular to the multifunctional region 181, and guiding and fixing functional region 183. A step is formed between the guiding and fixing functional region 183 and the surface mounting region 182. Similarly, the second pin electrode 19 is provided with multifunctional region 191, surface mounting region 192, and guiding and fixing functional region 193. The third pin electrode 21 is provided with multifunctional region 211, surface mounting region 212, and guiding and fixing functional region 213. The fourth pin electrode 22 is provided with multifunctional region 221, surface mounting region 222, and guiding and fixing functional region 223. The pin electrode is provided with a plurality of through-holes to prevent heat in the surface mounting region from being transferred to a fusible alloy point.

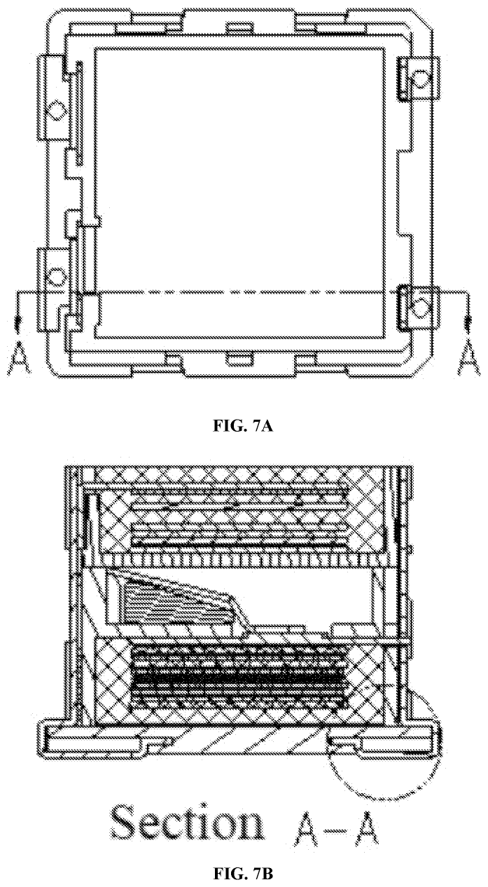

Corresponding to the four pin electrodes, the cover plate 20 is provided with first cavity 201, second cavity 202, a third cavity (not shown in the figure), and a fourth cavity (not shown in the figure). The guiding and fixing functional region 183 of the first pin electrode 18 is embedded in the first cavity 201 of the cover plate 20. The guiding and fixing functional region 193 of the second pin electrode 19 is embedded in the second cavity 202 of the cover plate 20. The guiding and fixing functional region 213 of the third pin electrode 21 is embedded in the third cavity of the cover plate 20. The guiding and fixing functional region 223 of the fourth pin electrode 22 is embedded into the fourth cavity of the cover plate 20. In this way, each pin electrode is fixed, and consistency between various planes of the surface mounting regions 182, 192, 212, and 222 is ensured. The housing 11 and the cover plate 20 are buckled to form an accommodating cavity. The accommodating cavity is provided with corresponding holes for leading the first pin electrode 18, the second pin electrode 19, the third pin electrode 21, and the fourth pin electrode 22 out of the accommodating cavity. This prevents the fusible alloy from being melted and disconnected due to hot air circulation during reflow soldering. As shown in FIGS. 7A-7B, an air gap of 0.1 mm to 1.5 mm is reserved between the housing 11 and the pin electrode in the accommodating cavity, which prevents heat absorbed by the housing from being directly transferred to the pin electrode and then to a solder point of the fusible alloy. As shown in FIG. 9, for the four pin electrodes, the multifunctional regions 181, 191, 211, and 221, and the surface mounting regions 182, 192, 212, and 222 are all exposed outside the accommodating cavity for surface mounting and soldering. The third pin electrode 21 and the fourth pin electrode 22 are led out of the accommodating cavity for testing. In another embodiment, the third pin electrode 21 and the fourth pin electrode 22 are not led out of the accommodating cavity as required. The multifunctional regions 181, 191, 211, and 221 can be easily used to detect, by using a CCD or other methods, whether the surface mounting regions 182, 192, 212, and 222 have inveracious soldering or excess soldering. In addition, the multifunctional regions 181, 191, 211, and 221 can also be used as side soldering regions to meet different soldering demands. The pin electrode is provided with at least one through-hole to prevent heat in the surface mounting region from being transferred to the fusible alloy point.

In a preferred embodiment, the first pin electrode 18, the second pin electrode 19, the third pin electrode 21, and the fourth pin electrode 22 are flat in shape, and each have a cross-sectional area of 0.1 mm² to 5 mm², a soldering area of 1 mm² to 75 mm², and a thickness of 0.2 mm to 1.5 mm. In this embodiment, the first pin electrode 18, the second pin electrode 19, the third pin electrode 21, and the fourth pin electrode 22 have different structures. In another embodiment, the first pin electrode 18 and the second pin electrode 19 may have a same structure or different structures, and the third pin electrode 21 and the fourth pin electrode 22 may have a same structure or different structures. In another embodiment, the first pin electrode 18, the second pin electrode 19, the third pin electrode 21, and the fourth pin electrode 22 may have a same structure.

### Embodiment 2

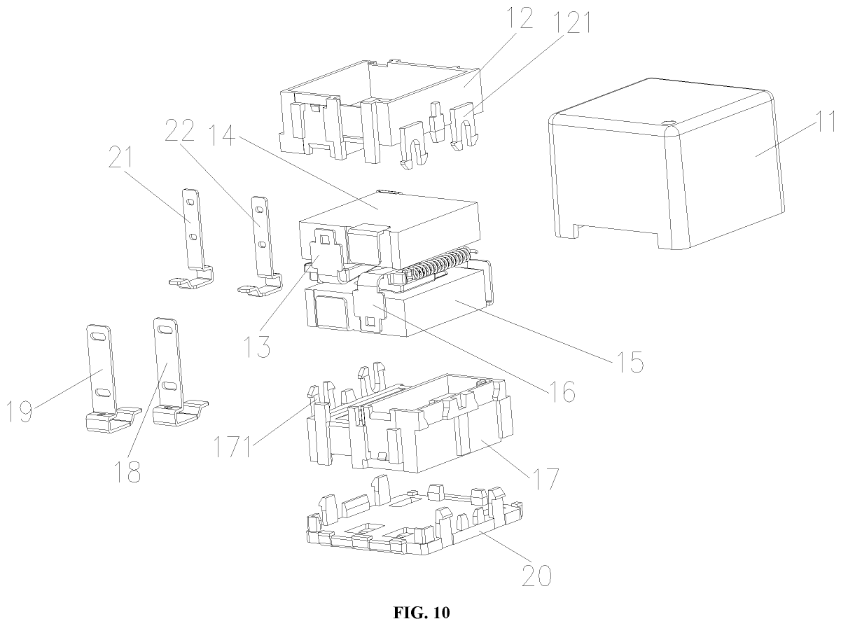

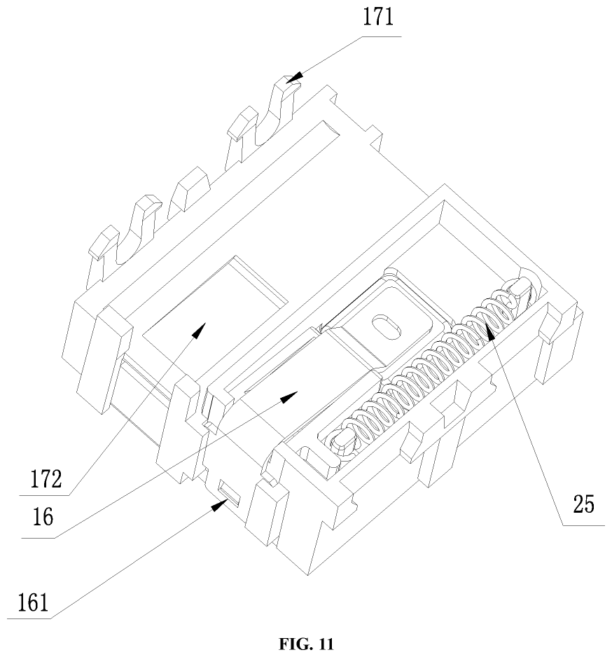

As shown in FIG. 10, this embodiment discloses a structure of another thermal-protection TVS, and content that is same as that in Embodiment 1 is not described herein again. Referring to FIG. 10 and FIG. 11, in this embodiment, the first inner frame 12 is provided with first buckle 121, and the second inner frame 17 is provided with second buckle 171. During installation, the first buckle 121 is engaged with a notch on the second inner frame 17, and the second buckle 171 is engaged with a notch on the first inner frame 12. In this embodiment, the first inner frame and the second inner frame have a same structure. Taking the second inner frame shown in the figure as an example, the second inner frame is provided with recess 172 to provided larger space for the first reed electrode 13 to bounce up. Correspondingly, the first inner frame is also provided with a recess to provided larger space for the second reed electrode 16 to bounce up. The first reed electrode and the second reed electrode have a same structure. Taking the second reed electrode 16 shown in the figure as an example, the second reed electrode 16 is provided with reed buckle 162 for fixing the second reed electrode 16 and the second inner frame 17, thereby preventing a reed from moving up, down, left, and right. The first thermal protection assistance device and the second thermal protection assistance device have a same structure. Taking the second thermal protection assistance device shown in FIG. 11 as an example, the spring 25 of the second thermal protection assistance device is a tension spring, with both ends hooked onto a convex column of the sliding member and a lug boss of the second inner frame 17 respectively. Similarly, the spring 24 of the first thermal protection assistance device is also a tension spring.

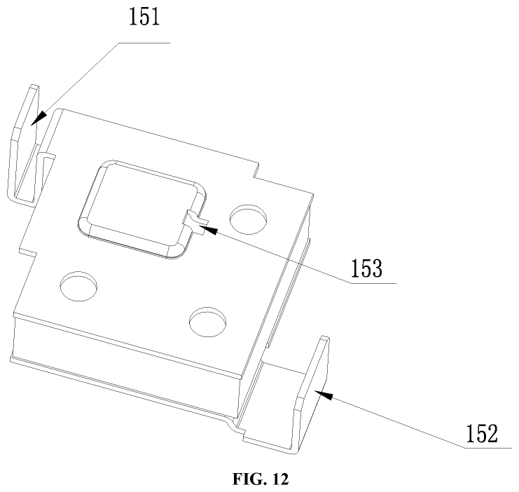

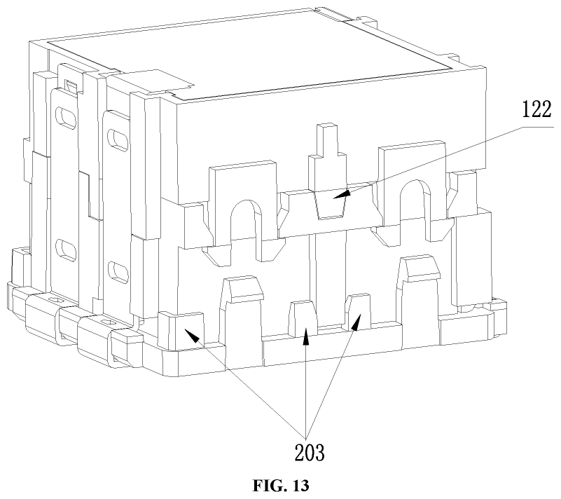

The first TVS chip 14 and the second TVS chip 15 have a same structure, as shown in FIG. 12. Taking the second TVS chip as an example, the second TVS chip 15 includes first electrode 151 and second electrode 152. The first electrode may be an integrated electrode or be formed by connecting a plurality of parts. There is a lug boss on the first electrode 151, and the lug boss is provided with gap 153 to reduce accumulation of thermal stress. In another embodiment, there may be no gap. In another embodiment, optionally, there may be one to eight gaps. In this example, a slot width of the gap is 0.3 mm. In another embodiment, the slot width of the gap is 10 mm. A structure of the first TVS chip is not described herein again.

Referring to FIG. 13, the cover plate 20 is also provided with limiting member 203 for limiting the inner frame. The first inner frame 12 is also provided with limiting protrusion 122, which is used for mutually clamping and limiting the first inner frame 12 and the second inner frame 17. A structure of the second inner frame 17 is the same as that of the first inner frame 12, and is not described herein again.

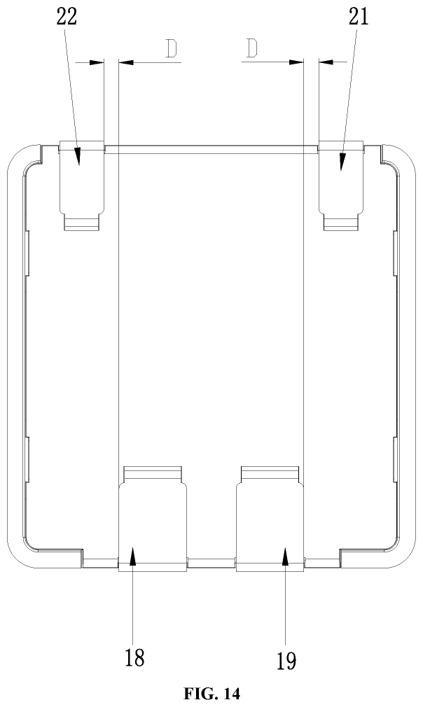

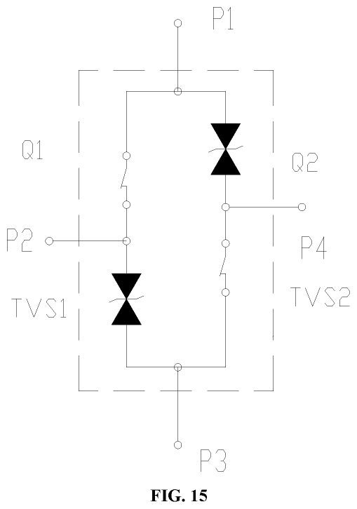

Referring to FIG. 14, the third pin electrode 21 and the fourth pin electrode 22 are located outside extension lines of outer edges of the first pin electrode 18 and the second pin electrode 19. Clearance D is formed between the outer edge of the first pin electrode 18 and an inner edge of the fourth pin electrode 22, and clearance D is formed between the outer edge of the second pin electrode 19 and an inner edge of the third pin electrode 21. The clearance D needs to be greater than zero, preferably ranges from 0.5 mm to 30 mm. The first pin electrode 18, the second pin electrode 19, the third pin electrode 21, and the fourth pin electrode 22 each have a corresponding solder pad position on a client. If a product is rotated 180 degrees for soldering, a placement error can be immediately identified (in this case, the product cannot be soldered and cannot be conducted), which plays a fool-proofing role.

The above described are merely preferred embodiments of the present disclosure and are not intended to limit the present disclosure in any form. Any changes, equivalent variations, and modifications made to the above embodiments based on the technical essence of the present disclosure without departing from the technical solutions of the present disclosure should fall within the scope defined by the technical solutions of the present disclosure.

What is claimed is:

1. A thermal-protection transient voltage suppressor (TVS), comprising a housing, a cover plate, a TVS assembly, and a pin electrode, wherein the housing and the cover plate are buckled to form an accommodating cavity, the TVS assembly and the pin electrode are accommodated in the accommodating cavity; the TVS assembly comprises an inner frame and a TVS chip accommodated in the inner frame; and the pin electrode extends outside the accommodating cavity and is equipped with a surface mounting region on an extending portion for surface mounting and soldering;
wherein the pin electrode comprises a main body of a straight-plate shape and a bending portion connected to the main body, the bending portion sequentially comprises a multifunctional region, the surface mounting region perpendicular to the multifunctional region, and a guiding and fixing functional region, and a step is formed between the guiding and fixing functional region and the surface mounting region.

2. The thermal-protection TVS according to claim 1, wherein the housing and the cover plate each are provided with a hole corresponding to the pin electrode, the bending portion of the pin electrode extends out of the accommodating cavity from the hole, and the multifunctional region, the surface mounting region, and the guiding and fixing functional region are exposed outside the accommodating cavity.

3. The thermal-protection TVS according to claim 1, wherein the cover plate is provided with a cavity corresponding to the pin electrode, and the guiding and fixing functional region of the pin electrode is embedded in the cavity of the cover plate.

4. The thermal-protection TVS according to claim 1, wherein the pin electrode is provided with at least one thermal resistance through-hole.

5. The thermal-protection TVS according to claim 1, wherein an air gap of 0.1 mm to 1.5 mm is reserved between the housing and the main body of the pin electrode in the accommodating cavity.

6. The thermal-protection TVS according to claim 1, wherein the pin electrode has a cross-sectional area of 0.1 mm² to 5 mm², the surface mounting region has a soldering area of 1 mm² to 75 mm², and the pin electrode has a thickness of 0.2 mm to 1.5 mm.

7. The thermal-protection TVS according to claim 1, wherein the TVS assembly further comprises a reed electrode and a thermal protection assistance device, the reed electrode is provided with a notch, and the thermal protection assistance device is disposed in the notch of the reed electrode, wherein the thermal protection assistance device comprises a sliding member and an elastic member, a first end of the elastic member is connected to the inner frame and a second end of the elastic member is connected to the sliding member, and the sliding member is subjected to an elastic force of the elastic member to enable the reed electrode to quickly trip and bounce up.

8. The thermal-protection TVS according to claim 1, wherein the pin electrode comprises a first pin electrode, a second pin electrode, a third pin electrode, and a fourth pin electrode, outer edges of the first pin electrode and the fourth pin electrode are aligned, and outer edges of the second pin electrode and the third pin electrode are aligned.

9. The thermal-protection TVS according to claim 1, wherein the pin electrode comprises a first pin electrode, a second pin electrode, a third pin electrode, and a fourth pin electrode, a first gap is provided between an extension line of an outer edge of the first pin electrode and an extension line of an inner edge of the fourth pin electrode, and a second gap is provided between an extension line of an outer edge of the second pin electrode and an extension line of an inner edge of the third pin electrode.

10. The thermal-protection TVS according to claim 2, wherein the cover plate is provided with a cavity corresponding to the pin electrode, and the guiding and fixing functional region of the pin electrode is embedded in the cavity of the cover plate.

11. The thermal-protection TVS according to claim 5, wherein the pin electrode has a cross-sectional area of 0.1 mm² to 5 mm², the surface mounting region has a soldering area of 1 mm² to 75 mm², and the pin electrode has a thickness of 0.2 mm to 1.5 mm.
